(19) United States
(12) Patent Application Publication
(10) Pub. No.: US 2006/0134828 A1
(43) Pub. Date: Jun. 22, 2006

(54) Package that integrates passive and active devices with or without a lead frame

(75) Inventor: Steven A. Kummerl, Carrollton, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/132,577

(22) Filed: May 18, 2005

Related U.S. Application Data
(60) Provisional application No. 60/637,479, filed on Dec. 17, 2004.

(51) Int. Cl. H01L 21/44; H01L 21/50; B23P 19/00

(52) U.S. Cl. 438/107

(57) ABSTRACT

According to an embodiment of the invention, a component package comprises a plurality of components and mold compound. The plurality of components are disposed on a zero plane of a removable substrate. The removal substrate is operable to hold the plurality of components in position. At least one of the plurality of components is wire bonded to at least another of the plurality of components with a wire bond. The mold compound is disposed around the plurality of components, encapsulating the plurality of components. A portion of the plurality of the components disposed upon the zero plane of the removable substrate are exposed upon removal of the substrate from the component package.

### CROSS-REFERENCE TO RELATED APPLICATIONS

Pursuant to 35 U.S.C. § 119 (e), this application claims priority from U.S. Provisional Patent Application Ser. No. 60/637,479, entitled NOVEL NEW PACKAGE THAT INTEGRATES PASSIVE AND ACTIVE DEVICES WITH OR WITHOUT A LEADFRAME, filed Dec. 17, 2004.

### TECHNICAL FIELD OF THE INVENTION

This invention relates generally to the field of semiconductor devices and, more particularly, to a package that integrates passive and active devices with or without a lead frame.

### BACKGROUND OF THE INVENTION

A packaged integrated circuit may generally include semiconductor chips and their associated components embedded within a molding. The packaged integrated circuits may be connected to a printed circuit board of an electronic device. Through the printed circuit board, the packaged integrated circuit may be connected to other chips and to external inputs and outputs.

### SUMMARY OF THE INVENTION

According to an embodiment of the invention, a component package comprises a plurality of components and mold compound. The plurality of components are disposed on a zero plane of a removable substrate. The removal substrate is operable to hold the plurality of components in position. At least one of the plurality of components is wire bonded to at least another of the plurality of components with a wire bond. The mold compound is disposed around the plurality of components, encapsulating the plurality of components. A portion of the plurality of the components disposed upon the zero plane of the removable substrate are exposed upon removal of the substrate from the component package.

Certain embodiments of the invention may provide numerous technical advantages. For example, a technical advantage of one embodiment may include the capability to reduce space requirements for a design with passives.

Although specific advantages have been enumerated above, various embodiments may include all, some, or none of the enumerated advantages. Additionally, other technical advantages may become readily apparent to one of ordinary skill in the art after review of the following figures and description.

### BRIEF DESCRIPTION OF THE DRAWINGS

For a more complete understanding of example embodiments of the present invention and its advantages, reference is now made to the following description, taken in conjunction with the accompanying drawings, in which:

FIG. 1A show an isometric view of a package portion, according to an embodiment of the invention;

FIG. 1B shows a passive component with a wire bond termination, according to an embodiment of the invention;

FIG. 1C shows a top cut away view of a package after a molding process of the package portion of FIG. 1A, according to an embodiment of the invention;

FIG. 1D shows a bottom view of the package of FIG. 1C with a substrate removed, according to an embodiment of the invention;

FIG. 1E shows a board layout, complementary to the package of FIG. 1D, according to an embodiment of the invention;

FIG. 2A shows an isometric view of a package portion, according to another embodiment of the invention;

FIG. 2B shows a top cut away view of a package after a molding process of the package portion of FIG. 2A, according to an embodiment of the invention;

FIG. 2C shows a bottom view of the package of FIG. 2B with the substrate removed, according to an embodiment of the invention;

FIG. 2D shows a board layout, complementary to the package of FIG. 2C, according to an embodiment of the invention;

FIG. 3A shows an isometric view of a package portion, according to yet another embodiment of the invention;

FIG. 3B shows a top cut away view of a package after a molding process of the package portion of FIG. 3A, according to another embodiment of the invention;

FIG. 3C shows a bottom view of the package of FIG. 3B with the substrate removed, according to another embodiment of the invention;

FIG. 3D shows a board layout, complementary to the package of FIG. 3C, according to an embodiment of the invention;

FIG. 4A shows an isometric view of a package portion, according to yet another embodiment of the invention;

FIG. 4B shows a bottom view of a package after a molding process of the package portion of FIG. 4A and removal of the substrate, according to an embodiment of the invention; and

FIG. 4C shows a board layout, complementary to the package of FIG. 4B, according to an embodiment of the invention.

### DETAILED DESCRIPTION OF EXAMPLE EMBODIMENTS OF THE INVENTION

It should be understood at the outset that although example embodiments of the present invention are illustrated below, the present invention may be implemented using any number of techniques, whether currently known or in existence. The present invention should in no way be limited to the example embodiments, drawings, and techniques illustrated below, including the embodiments and implementation illustrated and described herein. Additionally, the drawings are not necessarily drawn to scale.

In conventional integrated circuit packages, passive components disposed on the top of a lead frame can undesirably affect the height of the package. Additionally, some lead frame design requires a layout of critical passives on a board design, resulting in potential misroutes in the board's design. Accordingly, teachings of some embodiments of the invention recognize configurations that integrate passive components in a mold compound in a manner that allows passive components terminations to be used as an attachment means instead of an intermediate lead frame, thereby reducing and/or eliminating the critical passives for the board designer to layout. Teaching of some embodiments of the invention additionally recognize configurations that reduce the total “real estate” on a board. Although configurations of a packaged integrated circuit will be described with reference to particular embodiments herein, the packaged integrated circuit may include more, less, or different components than those described.

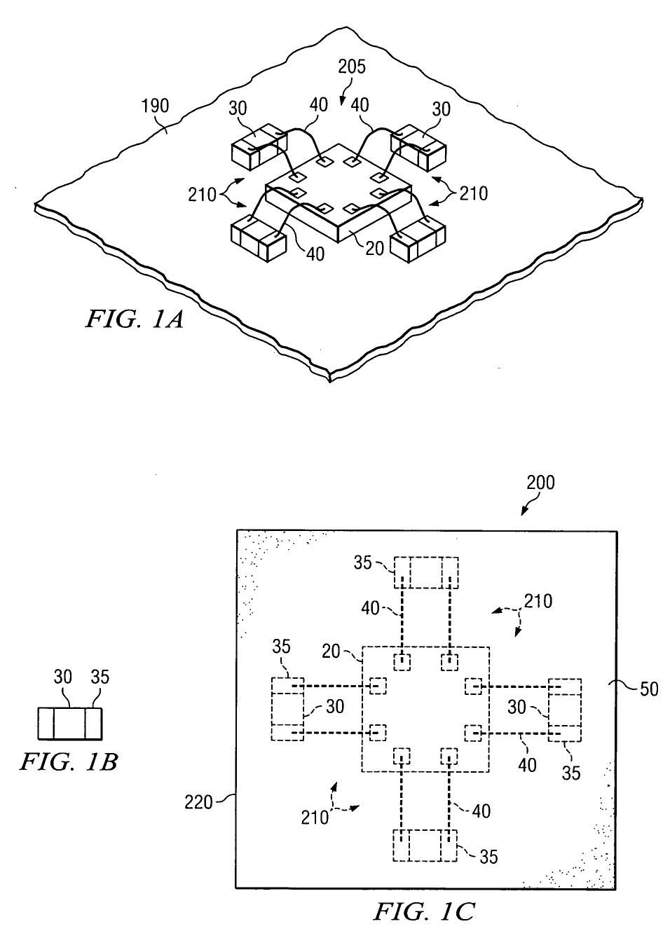

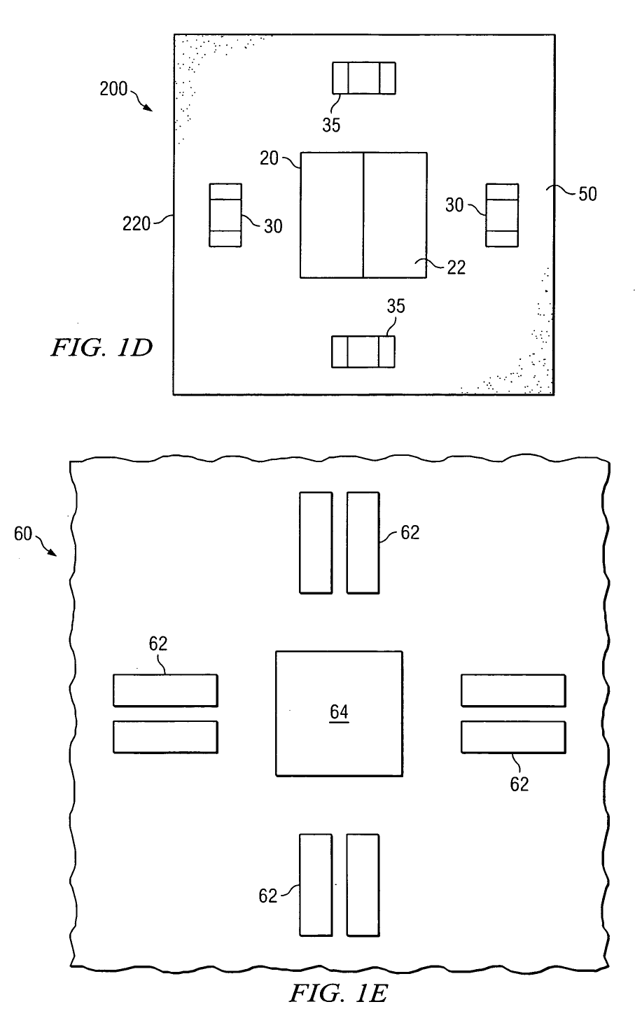

FIG. 1A show an isometric view of a package portion 205, according to an embodiment of the invention. The package portion 205 of FIG. 1A includes a plurality of components 210. The plurality of components 210 are shown disposed on top of a substrate 190. In particular embodiments, the substrate 190 may be a polyimide-based adhesive or tape operable to hold the component 210 in place and to withstand operating temperatures. “Withstanding operating temperatures” may generally refer to an ability of a the substrate 190 to hold the components in place 210 during an operation in which the substrate 190 will be utilized. For example, the substrate 190 may hold the components 210 in place during an injection molding process, described in further details below. A suitable adhesive or tape, according to one embodiment of the invention, is Kapton® tape. Although Kapton® tape has been described as a suitable substrate 190, other embodiments may utilize other suitable substrates 190 operable to hold components 210 in place and withstand operating temperatures.

In this embodiment, the substrate 190 creates a substantially planar surface upon which the components 210 are disposed. Accordingly, the substrate 190 may be considered the zero plane and the components 210, thus, are all positioned on the zero plane. With such a configuration, a vertical height in a package 200 may be reduced.

The components 210 in the embodiment of FIG. 1A are passive components 30 and a die or integrated circuit 20. The passive components 30 may include, but are not limited to capacitors, inductors, and resistors. The integrated circuit 20, alone or in combination with the passive components 30, may include a variety of different features, including, but not limited to, analog and/or digital circuits such as digital to analog converters, computer processor units, amplifiers, digital signal processors, controllers, transistors, or other semiconductor features. The integrated circuit 20 may comprise a variety of materials including silicon, gallium arsenide, or other suitable materials. To facilitate the communication between the integrated circuit 20 and the passive component 30, the passive components have a wire bond 40 positioned therebetween. Accordingly, the passive components 30 include a wire bond termination 35 as shown in FIG. 1B.

In operation, after the components 210 have been placed on the substrate 190, the package portion 205 may be forwarded to a wire bonding process that places the wire bonds 40 between the components 210. Then, the package portion 205 may be forwarded to a molding process to place molding 50 (not explicitly shown) around the components 210 in order to form a package 200 as shown in FIG. 1C. One suitable molding process is an injection molding process. However, other suitable molding process may be utilized to place mold compound 50 around the components 210.

FIG. 1C shows a top cut away view of a package 400 after a molding process of the package portion 405 of FIG. 1A, according to an embodiment of the invention. A mold compound 50 generally surrounds and holds the integrated circuit 20, passive components 30, and the wire bonds 40 in position. Accordingly, after the molding process, the substrate 190 may be removed, exposing the integrated circuit 20 and passive components 30 as shown in FIG. 1D. Any suitable mold compound operable to encapsulate components 210 may be utilized. Examples include, but are not limited to, a “green” mold compound that does not contain bromine (Br) or antimony (Sb). Although such mold compounds have been described, other suitable mold compounds operable to hold the components 210 in place may be utilized.

In operation, a plurality of packages 200 may be coupled to one another, during processing, and separated from one another after processing, using suitable separation processes, including, but not limited to, sawing or punching. Accordingly, the package 200 as shown in FIG. 1C may includes a pull back feature—that is, placement of components 210 at a distance from an edge 220 of the package 200. Such a pull back features helps ensure that the components 210 will not become damages during separation of the packages 200.

FIG. 1D shows a bottom view of the package 200 of FIG. 1C with the substrate 190 removed, according to an embodiment of the invention. With the substrate 190 removed, the components 210 are all exposed at the zero plane. In some embodiments, a metal may be placed on a backside 22 of the integrated circuit 20 to facilitate a soldering or other suitable coupling process. Alternatively, an insulation material may be placed on the backside 22 of the integrated circuit 20 to facilitate configurations in which insulation may be desired.

FIG. 1E shows a board layout 60, complementary to the package 200 of FIG. 1D, according to an embodiment of the invention. Portions 62 of the board layout 60 corresponds to the passive components 30 and portion 64 of the board layout 60 corresponds to the integrated circuit 20. A variety of techniques may be utilized to establishing communication between the package 200 and the board layout 60, including, but not limited to, soldering. In some embodiments, the package 200 may retain the substrate 190 for shipping and removed upon arrival at a location at which the package 200 is installed on the board layout 60. In such embodiments, the substrate 190 may serve to protect components 210 that would otherwise be exposed without the substrate 190.

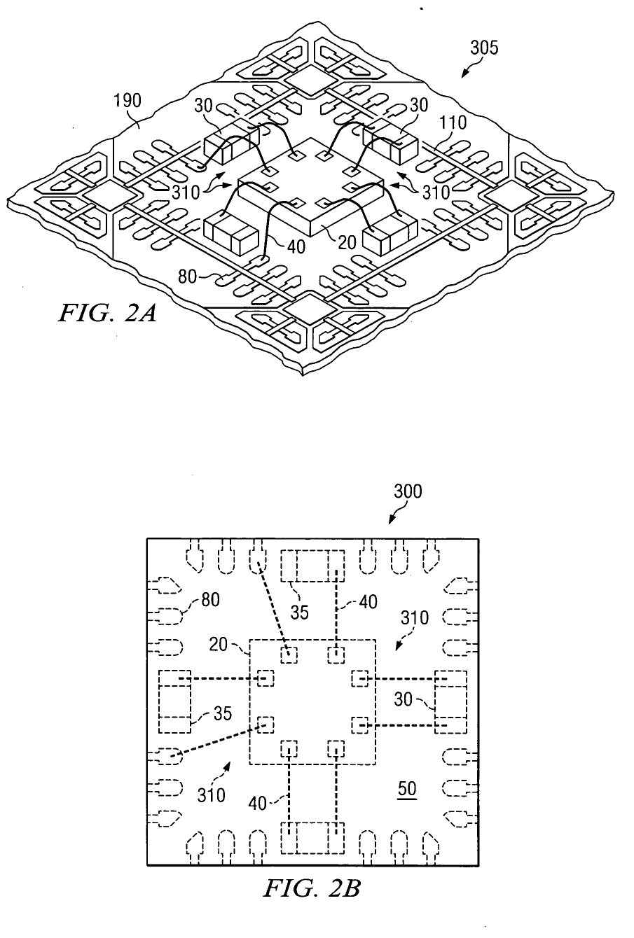

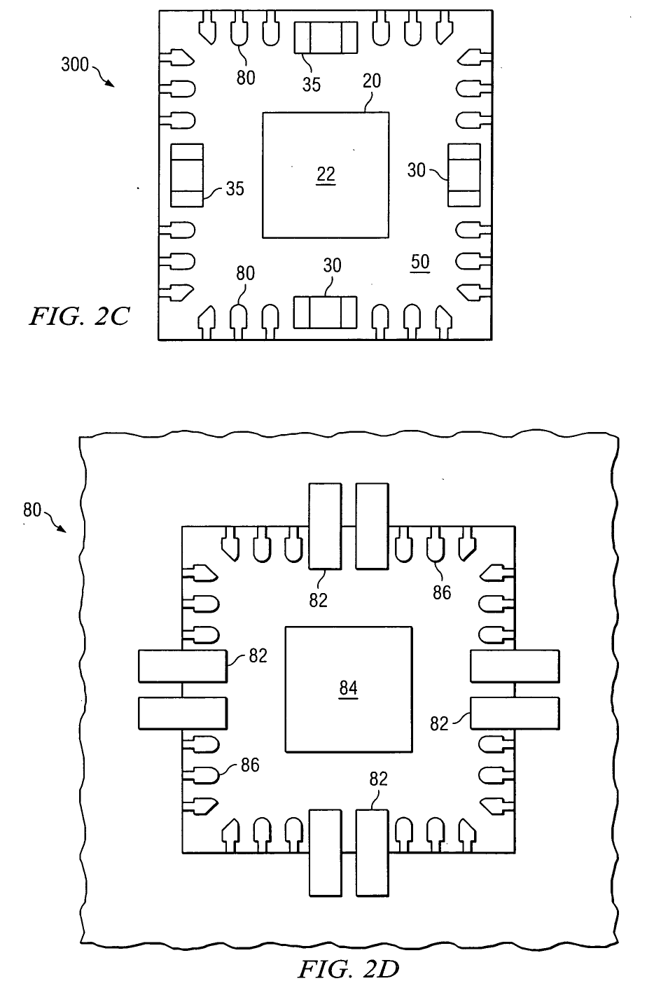

FIG. 2A shows an isometric view of a package portion 305, according to another embodiment of the invention. In this embodiment, the package portion 305 includes components 310. Components 310 may include similar or different components than the components 210 shown in FIG. 1A. In this embodiment, the components 310 are shown as an integrated circuit 20, passive components 30, and bond pads 80. To facilitate communication amongst the components 310, wire bonds 40 are positioned therebetween. For example, wire bonds 40 are shown between the integrated circuit 20 and a bond pad 80 and between the integrated circuit 20 and a passive component 30. Similar to that described above with reference to FIG. 1A, the components 310 and a lead frame 110 are positioned on top of a substrate 190, which may be made of similar or different materials than the substrate 190 described with reference to FIG. 1A. The package portion 305 may be packaged into a package 300 in a similar manner to that described above with reference to FIG. 1A—that is, placing the components 310 on the substrate 190, wire bonding the components 310 in the applicable locations, placing molding around the components 310, and separating the package 300 from other packages when the packages are assembled in a group.

FIG. 2B shows a top cut away view of a package 300 after a molding process of the package portion 305 of FIG. 2A, according to an embodiment of the invention. The package 300 may be a package separated from an assembly of multiple packages as described above. In a manner similar to that described with reference to FIG. 1C, a mold compound 50 surrounds and holds the integrated circuit 20, passive components 30, pads 80, and wire bonds 40 in position. After the molding process, the substrate 190 may be removed, exposing the integrated circuit 20, passive components 30, and pads 80 as shown in FIG. 2C. Similar to that described with reference to FIG. 1A, the mold compound 50 may be made of any suitable material operable to hold the components 310 in position. Additionally, the package 300 may include a pull back feature.

FIG. 2C shows a bottom view of the package 300 of FIG. 2B with the substrate 190 removed, according to an embodiment of the invention. With the substrate 190 removed, the components 210 are all exposed at the zero plane. Similar to that described with reference to FIG. 1D, a metal may be placed on a backside 22 of the integrated circuit 20 to facilitate a soldering or other suitable coupling process. Alternatively, an insulation material may be placed on the backside 22 of the integrated circuit 20 to facilitate configurations in which insulation may be desired.

FIG. 2D shows a board layout 80, complementary to the package 300 of FIG. 2C, according to an embodiment of the invention. Portions 82 of the board layout 80 correspond to the passive components 30, portion 84 of the board layout 80 corresponds to the integrated circuit 20, and portions 86 of the board layout 80 correspond to the bond pads 80. Similar to that described above with reference to FIG. 1E, a variety of techniques may be utilized to establish communication between the package 300 and the board layout 80, including, but not limited to soldering. Additionally, in some embodiments the substrate 190 may be retained for shipping and removed upon arrival at a location at which the package 300 is installed on the board layout 80.

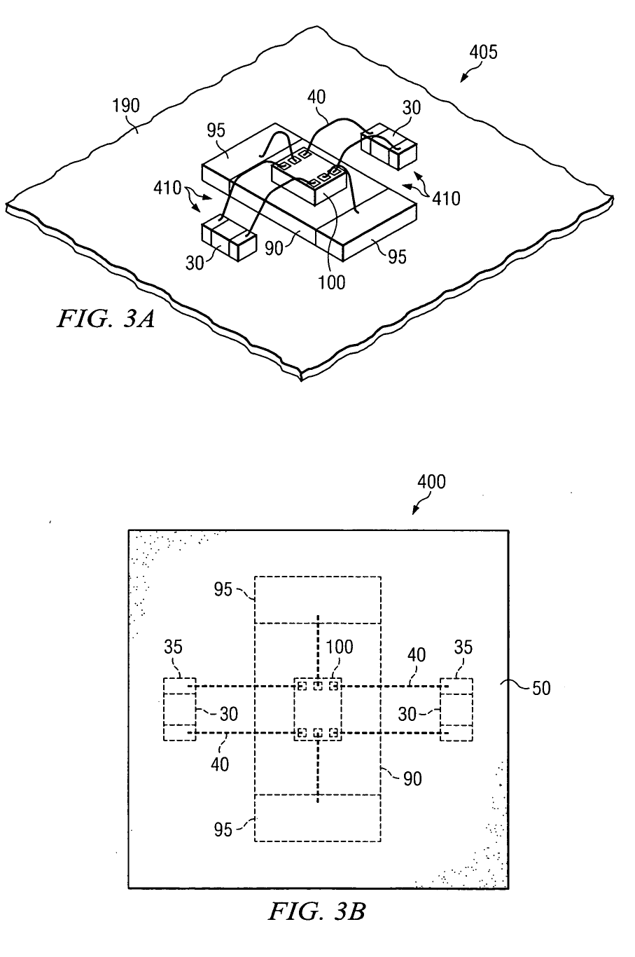

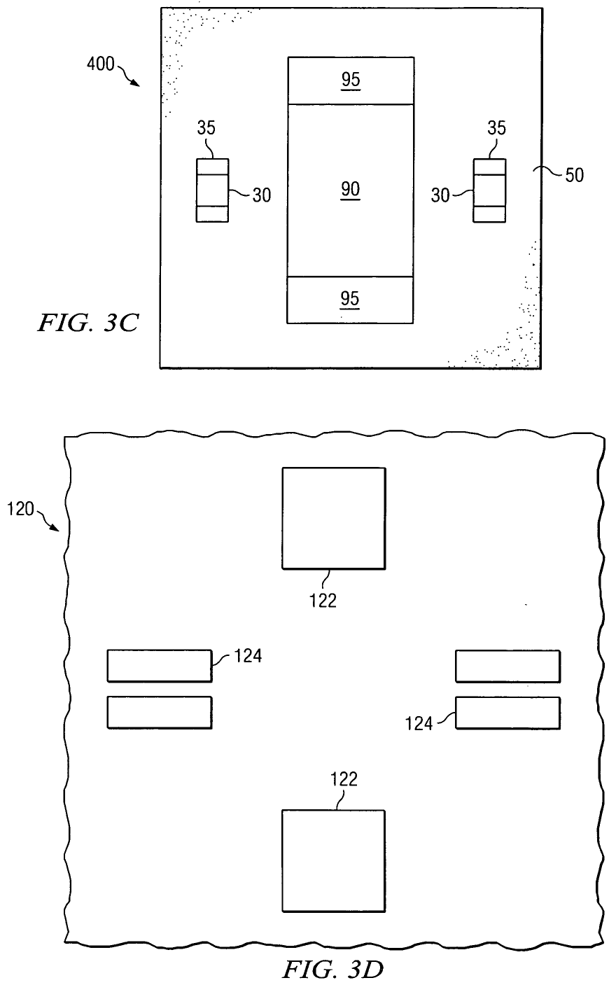

FIG. 3A shows an isometric view of a package portion 405, according to yet another embodiment of the invention. In this embodiment, the package portion 405 includes components 410. Components 410 may include similar or different components than the components 210 shown in FIG. 1A. In this embodiment, the components 410 are shown as a passive component 90, passive components 30, and an integrated circuit 100. The passive component 90 may be similar or different than passive components 30. For example, passive components 90 may include wire bond terminations 95. The integrated circuit 100 may be coupled to the top of the passive component 90. Although not explicitly shown, the integrated circuit 100 may be attached to the top of the passive component 90, utilizing a variety of attachment mediums, including epoxy, polyimide, other adhesive chemistries, mixture of such chemistries, solder, a gold-silicon Eutectic layer, or other suitable material and/or materials for bonding the integrated circuit 100 to the passive component 90. To facilitate communication amongst the components 410, wire bonds 40 are positioned therebetween. For example, wire bonds 40 are shown between the integrated circuit 100 and the passive component 30 and between the passive component 90 and the integrated circuit 40. Similar to that described above with reference to FIGS. 1A and 2A, the passive component 90 and the passive components 30 are positioned on top of a substrate 190, which may be made of similar or different materials than that described with reference to FIG. 1A. The package portion 405 may be packaged into a package 400 in a similar manner to that described above with reference to FIGS. 1A and 2A—that is, placing the components 410 on the substrate 190 and/or on top of one another (e.g., placing the integrated circuit 100 on the passive component 90 using techniques described above or other suitable techniques), wire bonding the components 410 in the applicable locations, placing molding around the components 410, and separating the package 400 from other packages when the packages are assembled in a group.

FIG. 3B shows a top cut away view of a package 400 after a molding process of the package portion 405 of FIG. 3A, according to another embodiment of the invention. The package 400 may be a package separated from an assembly of multiple packages as described above. In a manner similar to that described with reference to FIG. 1B, a mold compound 50 surrounds and holds the integrated circuit 100, passive components 30, and passive component 90 in position. After the molding process, the substrate 190 may be removed, exposing the passive components 30 and passive component 90 as shown in FIG. 3C.

FIG. 3C shows a bottom view of the package 400 of FIG. 3B with the substrate 190 removed, according to another embodiment of the invention. With the substrate 190 removed, the components passive components 30 and passive component 90 are exposed at the zero plane. Similar to that described with reference to FIG. 1C, a metal may be placed on a backside 22 of the integrated circuit 20 to facilitate a soldering or other suitable coupling process. Alternatively, an insulation material may be placed on the backside 22 of the integrated circuit 20 to facilitate configurations in which insulation may be desired.

FIG. 3D shows a board layout 120, complementary to the package 400 of FIG. 3C, according to an embodiment of the invention. Portions 122 of the board layout 120 corresponds to the passive component 90 and portion 124 of the board layout 120 corresponds to the passive components 30. Similar to that described above, a variety of techniques may be utilized to establish communication between the package 400 and the board layout 120, including, but not limited to soldering. Additionally, in some embodiments the substrate 190 may be retained for shipping and removed upon arrival at a location at which the package 400 is installed on the board layout 120.

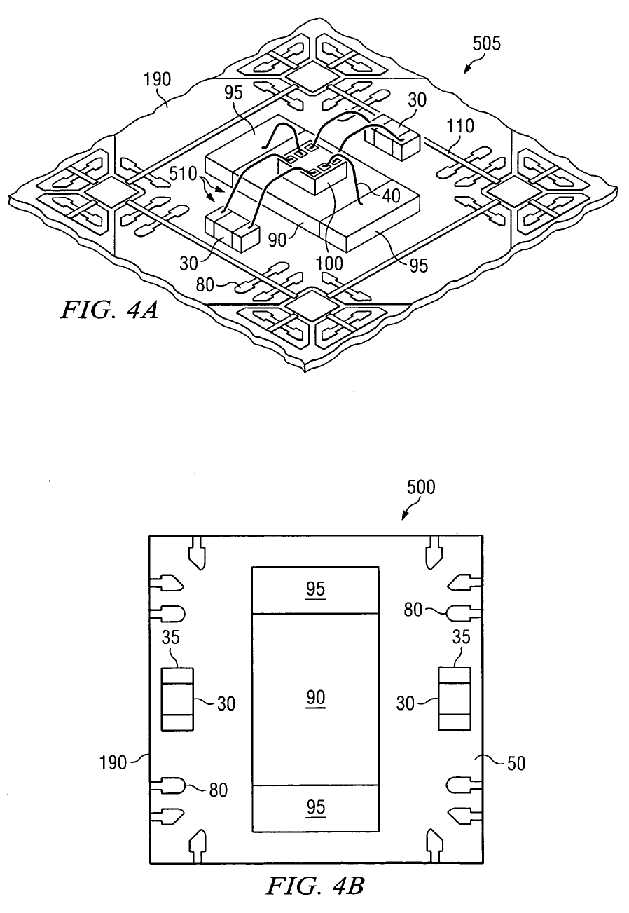

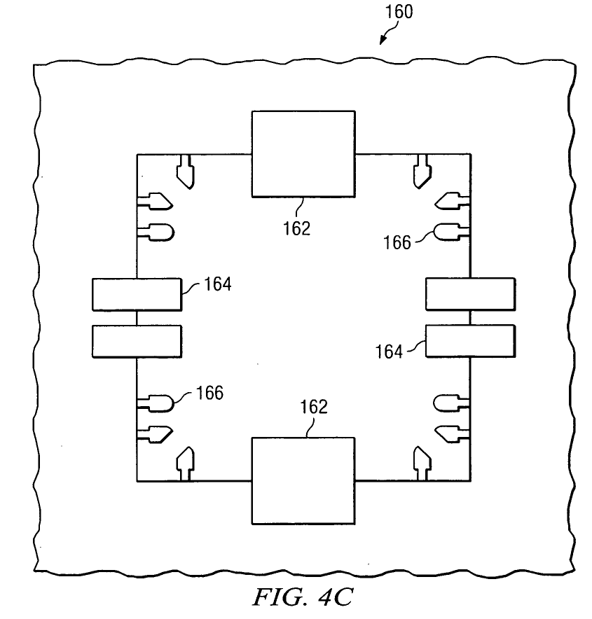

FIG. 4A shows an isometric view of a package portion 505, according to yet another embodiment of the invention. In this embodiment, the package portion 505 includes components 510. Components 510 may include similar or different components than the components 510 shown in FIG. 3A. In this embodiment, the components 510 are shown as a passive component 90, passive components 30, an integrated circuit 100, and bond pads 80. To facilitate communication amongst these components 510, wire bonds 40 are positioned therebetween. For example, wire bonds 40 are shown between the integrated circuit 100 and passive component 30, between the passive component 90 and the integrated circuit 40. Similar to that described above with reference to FIGS. 2A and 3A, the integrated circuit 100 may be attached to the top of the passive component 90 and the passive component 90, passive components 30, bond pads 80, and a lead frame 110 are positioned on top of a substrate 190, which may be made of similar or different materials than that described with reference to FIG. 1A. The package portion 505 may be packaged into a package 500 in a similar manner to that described above with reference to FIGS. 1A, 2A, and 3A—that is, placing the components 510 on the substrate 190 and/or on top of one another (e.g., placing the integrated circuit 100 on the passive component 90 using techniques described above or other suitable techniques), wire bonding the components 510 in the applicable locations, placing molding around the components 510, and separating the package 500 from other packages when the packages are assembled in a group.

FIG. 4B shows a bottom view of the package 500 after a molding process of the package portion 505 of FIG. 4A and removal of the substrate 190, according to an embodiment of the invention. The package 500 may be a package separated from an assembly of multiple packages as described above. A mold compound 50 surrounds and holds the integrated circuit 100, passive components 30, passive component 90, and bond pads 80 in position. Similar to that described with reference to FIG. 1A, the mold compound 50 may be made of any suitable material operable to hold the components 510 in position. Additionally, the package 500 may include a pull back feature. After the molding process, the substrate 190 may be removed, exposing the passive components 30, passive component 90, and bond pads 80 at the zero plane.

FIG. 4C shows a board layout 160, complementary to the package 500 of FIG. 4B, according to an embodiment of the invention. Portions 162 of the board layout 160 correspond to the passive component 90, portions 164 of the board layout 160 correspond to the passive components 30, and portions 166 of the board layout 160 correspond to the bond pads 80. Similar to that described above, a variety of techniques may be utilized to establish communication between the package 500 and the board layout 160, including, but not limited to soldering. Additionally, in some embodiments the substrate 190 may be retained for shipping and removed upon arrival at a location at which the package 500 is installed on the board layout 160.

Although components have been described have been described above with reference to FIGS. 1A-4C as passive components and integrated circuits, other components may additionally be incorporated into the package.

Although the present invention has been described with several embodiments, a myriad of changes, variations, alterations, transformations, and modifications may be suggested to one skilled in the art, and it is intended that the present invention encompass such changes, variations, alterations, transformation, and modifications as they fall within the scope of the appended claims.

What is claimed is:

1. A method of providing a component package, the method comprising:
disposing a plurality of components on a zero plane of a removable substrate, the plurality of components comprising at least an integrated circuit and at least one passive component;
wire bonding, via a wire bond, the integrated circuit to the at least one passive component;
injection molding a mold compound around the plurality of components to form the component package, the removable substrate holding the plurality of components in position during the injection molding and the mold compound encapsulating the plurality of components;
removing the removable substrate;
exposing a portion of the integrated circuit disposed on the removal substrate; and
exposing a portion of the at least one passive component disposed on the removal substrate.

2. The method of claim 1, wherein the plurality of components further comprise at least one bond pad, further comprising:
wire bonding, via a wire bond, the integrated circuit to the bond pad before injection molding; and
exposing a portion of the at least one bond pad disposed on the removal substrate after removal of the removable substrate.

3. The method of claim 1, wherein the removable substrate is an adhesive tape.

4. The method of claim 1, further comprising:
transporting the component package to a desired location prior to removing the removable substrate; and
establishing communication between the component package and a complementary board after removal of the removable substrate.

5. A component package comprising:
a plurality of components disposed on a zero plane of a removable substrate, the removal substrate operable to hold the plurality of components in position and at least one of the plurality of components wire bonded to at least another of the plurality of components with a wire bond;
a mold compound disposed around the plurality of components, the mold compound encapsulating the plurality of components; and
wherein a portion of the plurality of the components disposed upon the zero plane of the removable substrate are exposed upon removal of the substrate from the component package.

6. The component package of claim 1, wherein at least one of the plurality of components is at least one integrated circuit.

7. The component package of claim 6, wherein at least another of the plurality of components is at least one passive component.

8. The component package of claim 7, wherein at least another of the plurality of components is at least one bond pad.

9. The component package of claim 8, wherein the at least one integrated circuit is wire bonded to the at least one bond pad and the at least one passive component.

10. The component package of claim 6, wherein at least another of the plurality of components is at least one bond pad.

11. The component package of claim 7, further comprising:
an integrated circuit disposed on top of the passive component.

12. The component package of claim 1, wherein the substrate is an adhesive tape.

13. The component package of claim 1, wherein the mold compound is an injection molding compound.

14. A method of providing a component package, the method comprising:
disposing a plurality of components on a zero plane of a removable substrate;
wire bonding at least one of the components to at least another of the components;
disposing a mold compound on the plurality of components, the removable substrate holding the components in position during the disposing of the mold compound;
removing the removable substrate; and
exposing a portion of the plurality of the components disposed upon the zero plane of the removable substrate.

15. The method of claim 14, wherein at least one of the plurality of components is an integrated circuit, further comprising:
placing metal on the exposed portion of the integrated circuit after removing the removable substrate.

16. The method of claim 15, wherein
at least one of the plurality of components is a passive component, and
wire bonding at least one of the components to at least another of the components includes wire bonding the integrated circuit to the at least one passive component.

17. The method of claim 16, wherein
at least another of the plurality of components is at least one bond pad; and
wire bonding at least one of the components to at least another of the components further includes wire bonding the integrated circuit to the at least one bond pad.

18. The method of claim 14, further comprising:
establishing communication between the component package and a complementary board after removal of the removable substrate.

19. The method of claim 14, further comprising:
transporting the component package to a desired location prior to removing the removable substrate; and
establishing communication between the component package and a complementary board after removal of the removable substrate.

20. The method of claim 14, wherein at least one of the plurality of components is a passive component, further comprising:
disposing an integrated circuit on top of the passive component.
